(19) United States
(12) Patent Application Publication
(10) Pub. No.: US 2022/0293418 A1
(43) Pub. Date: Sep. 15, 2022

(54) SEMICONDUCTOR MANUFACTURING APPARATUS AND SEMICONDUCTOR MANUFACTURING METHOD

(71) Applicant: Kioxia Corporation, Tokyo (JP)

(72) Inventors: Takuya MIZUTANI, Yokkaichi Mie (JP); Nobuhiro KOMINE, Nagoya Aichi (JP)

(73) Assignee: Kioxia Corporation, Tokyo (JP)

(21) Appl. No.: 17/471,209

(22) Filed: Sep. 10, 2021

(30) Foreign Application Priority Data
Mar. 9, 2021 (JP) 2021-037784

(51) Int. Cl. H01L 21/02; H01L 21/687; G03F 7/16

(52) U.S. Cl. CPC H01L 21/02282; H01L 21/68764; H01L 21/02318; H01L 21/02118; G03F 7/162; G03F 7/168

(57) ABSTRACT

A semiconductor manufacturing apparatus according to an embodiment includes a rotor, a nozzle, a first electrode, and a second electrode. The rotor is configured to hold a substrate and to rotate the substrate. The substrate has an outer-periphery portion and a circumferential edge. The circumferential edge is located outside the outer-periphery portion. The nozzle is configured to supply a resist liquid to the outer-periphery portion of the substrate. The first electrode is configured to receive a voltage that applies an electric charge to the resist liquid ejected from the nozzle. The second electrode is disposed at a position different from that of the first electrode. The second electrode is configured to receive a voltage that causes a Coulomb force to act on the resist liquid.

### CROSS-REFERENCE TO RELATED APPLICATION

This application is based upon and claims the benefit of priority from Japanese Patent Application No. 2021-037784, filed Mar. 9, 2021; the entire contents of which are incorporated herein by reference.

### FIELD

Embodiments described herein relate generally to a semiconductor manufacturing apparatus and a semiconductor manufacturing method.

### BACKGROUND

As a semiconductor manufacturing process, a resist coating method of applying a resist to an outer-periphery portion of a substrate is known.

### BRIEF DESCRIPTION OF THE DRAWINGS

FIG. 1 is a schematic configuration diagram showing an entire configuration of a resist coater according to a first embodiment.

FIG. 2 is a schematic cross-sectional view showing a relevant part of the resist coater according to the first embodiment and a configuration of a silicon substrate.

FIG. 3 is a perspective view showing a relevant part of the resist coater according to the first embodiment.

FIG. 4 is a perspective view showing a relevant part of the resist coater according to a second embodiment.

FIG. 5 is a perspective view showing a relevant part of the resist coater according to a third embodiment.

### DETAILED DESCRIPTION

A semiconductor manufacturing apparatus according to an embodiment includes a rotor, a nozzle, a first electrode, and a second electrode. The rotor is configured to hold a substrate and to rotate the substrate. The substrate has an outer-periphery portion and a circumferential edge. The circumferential edge is located outside the outer-periphery portion. The nozzle is configured to supply a resist liquid to the outer-periphery portion of the substrate. The first electrode is configured to receive a voltage that applies an electric charge to the resist liquid ejected from the nozzle. The second electrode is disposed at a position different from that of the first electrode. The second electrode is configured to receive a voltage that causes a Coulomb force to act on the resist liquid.

Hereinafter, a resist coater (semiconductor manufacturing apparatus) and a resist coating method (semiconductor manufacturing method) according to an embodiment will be described with reference to the drawings.

In the following description, the same reference signs are given to components having the same or similar function. Duplicate description of these components may be omitted. The drawings are schematic or conceptual, and a relationship between a thickness and a width of each portion, ratios of sizes between portions, or the like are not necessarily the same as in reality.

An X-direction, a Y-direction, a Z-direction, and a radial direction will be defined in advance. The X-direction and the Y-direction are directions that are parallel to a silicon substrate 5 which will be described later. The Z-direction is a direction that intersects with (for example, is orthogonal to) the X-direction and the Y-direction. In other words, the Z-direction is a thickness direction of the silicon substrate 5 and is a direction perpendicular to the silicon substrate 5. In the Z-direction, a direction from a nozzle 21 which will be described later to the silicon substrate 5 may be referred to as a plan view. A direction from a center of the silicon substrate 5 to a circumferential edge 5E may be referred to as a “radially outward direction of the silicon substrate 5” or may be simply referred to as a “radially outward direction”.

### First Embodiment

### <Entire Configuration of Resist Coater>

First of all, an entire configuration of a resist coater 1 according to a first embodiment will be described.

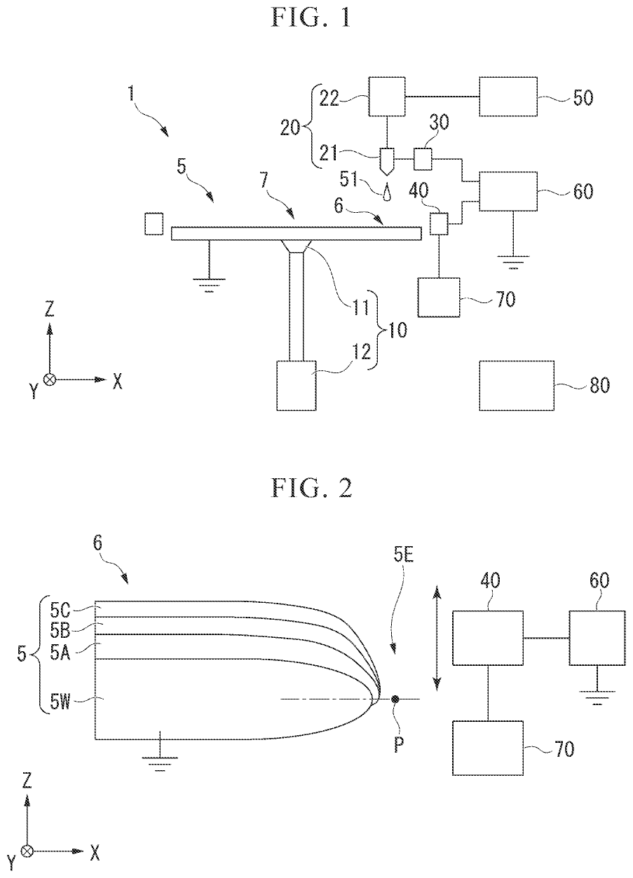

FIG. 1 is a schematic configuration diagram showing a configuration of the resist coater 1. FIG. 2 is a schematic cross-sectional view showing a relevant part of the resist coater 1 and a configuration of the silicon substrate 5.

The resist coater 1 includes, for example, a rotor 10, an ejector 20, a first electrode 30, a second electrode 40, a resist supply source 50, a power supply 60, an electrode mover 70, and a controller 80. The resist coater 1 is configured to apply a resist liquid 51 to an outer-periphery portion 6 of the silicon substrate 5 and to dry the resist liquid 51 while rotating the silicon substrate 5, and thereby to form a resist film on the outer-periphery portion 6.

### <Silicon Substrate>

A base member 5W forming the silicon substrate 5 is formed of a known disk-shaped semiconductor wafer. The silicon substrate 5 has a center region 7 and the outer-periphery portion 6. The center region 7 includes a center of the silicon substrate 5. The outer-periphery portion 6 is located outside the center region 7 in the X-direction and the Y-direction. The silicon substrate 5 has a circumferential edge 5E.

The circumferential edge 5E is located outside the outer-periphery portion 6. The outer-periphery portion 6 has a curved surface formed by chamfering the circumferential edge 5E of the base member 5W.

A first layer 5A, a second layer 5B, and a third layer 5C are layered on the base member 5W of the silicon substrate 5. As the kind of layers of the first layer 5A, the second layer 5B, and the third layer 5C, for example, a metal layer, a semiconductor layer, an insulating layer, a carbon layer, or the like is adopted. Note that, the kind of layers forming a layered structure on the silicon substrate 5 is not limited to this embodiment. Moreover, the number of layers forming the layered structure is not limited to this embodiment.

### <Rotor>

The rotor 10 includes a spin chuck 11 and a motor 12. The spin chuck 11 is configured to hold the silicon substrate 5 (substrate) mounted on the rotor 10. The motor 12 is configured to rotate the spin chuck 11. The spin chuck 11 holds the silicon substrate 5, for example, by suctioning a back surface of the silicon substrate 5. Furthermore, the spin chuck 11 is connected to the ground, and therefore the electrical potential of the silicon substrate 5 is the ground potential.

The motor 12 rotates the spin chuck 11 and thereby rotates the silicon substrate 5 held by the spin chuck 11.

The rotating speed of the silicon substrate 5 is not particularly limited. The rotating speed is set in accordance with known application conditions such as the kind and a degree of viscosity of the resist liquid 51 to be applied to the outer-periphery portion 6 of the silicon substrate 5, a film thickness required for the resist film, or the like.

### <Resist Supply Source>

The resist supply source 50 stores the resist liquid 51 to be used in the resist coater 1. The resist supply source 50 supplies the resist liquid 51 to the ejector 20. The kind of the resist liquid 51 is not particularly limited.

### <Ejector>

The ejector 20 includes the nozzle 21 and a nozzle-position adjuster 22.

The nozzle 21 is connected to the resist supply source 50. The resist liquid 51 is supplied from the resist supply source 50 to the nozzle 21. The nozzle 21 is configured to supply the resist liquid 51 to the outer-periphery portion 6 of the silicon substrate 5. For example, the nozzle 21 is disposed at a position at which the silicon substrate 5 faces the nozzle 21 in the Z-direction (particularly, above the silicon substrate 5).

The nozzle-position adjuster 22 can move the nozzle 21 in the X-direction and the Y-direction.

Furthermore, the nozzle-position adjuster 22 can adjust the angle of the nozzle 21 with respect to the silicon substrate 5. That is, the nozzle-position adjuster 22 can change an ejection direction (ejection angle) of the resist liquid 51 ejected from the nozzle 21 with respect to the silicon substrate 5. As the nozzle-position adjuster 22 is driven, the nozzle 21 can eject the resist liquid 51 at a desired ejection angle with respect to the silicon substrate 5.

### <First Electrode>

The first electrode 30 is connected to, for example, the nozzle 21 and the power supply 60. The first electrode 30 is configured to receive a voltage from the power supply 60. The voltage of the first electrode 30 applies an electric charge to the resist liquid ejected from the nozzle 21. When a direct-current voltage is supplied from the power supply 60 to the first electrode 30, the voltage of the first electrode 30 is applied to the nozzle 21, and an electric charge is applied to the resist liquid 51 ejected from the nozzle 21. Because of this, the resist liquid 51 has an electrostatic charge.

The electric charge applied to the resist liquid 51 by the first electrode 30 is selected by the power supply 60. The electric charge applied to the resist liquid 51 may be a first polarity electric charge (for example, a negative electric charge). The electric charge applied to the resist liquid 51 may be an electric charge having a second polarity which is opposite to the first polarity (for example, a positive electric charge).

For example, the first electrode 30 may be provided separately from the nozzle 21, and the first electrode 30 may be provided integrally with the nozzle 21. When the first electrode 30 and the nozzle 21 are provided to be combined together, an external form member (metal member) forming the outer shape of the nozzle 21 may function as the first electrode 30.

### <Second Electrode>

The second electrode 40 is disposed at a position different from that of the first electrode 30. The second electrode 40 is configured to receive a voltage from the power supply 60. The voltage of the second electrode 40 causes a Coulomb force to act on the resist liquid 51 such that at least part of the resist liquid 51 flows toward the circumferential edge 5E of the silicon substrate 5. In other words, the second electrode 40 causes a Coulomb force to act on the resist liquid 51 so as to guide at least part of the resist liquid 51 toward the circumferential edge 5E of the silicon substrate 5.

Here, of the resist liquid 51 applied on the silicon substrate 5, “at least part of the resist liquid 51” may be, for example, at least part of an exposed portion (surface layer) of the resist liquid 51 which is exposed to a space above the silicon substrate 5. Additionally, “at least part of the resist liquid 51 flows toward the circumferential edge 5E of the silicon substrate 5” may mean that at least part of the resist liquid 51 having a protruding shape protruding from a flat surface of the resist liquid 51 flows toward the circumferential edge 5E of the silicon substrate 5 via the action of the Coulomb force while remaining the resist liquid 51 having the flat surface on the outer-periphery portion 6 of the silicon substrate 5.

The second electrode 40 is connected to, for example, the power supply 60. When a direct-current voltage is supplied from the power supply 60 to the second electrode 40, an electric charge is applied to the second electrode 40. The electric charge applied to the second electrode 40 is the electric charge having a second polarity which is opposite to the first polarity (for example, a positive electric charge). As described later, the second electrode 40 generates a Coulomb force between the resist liquid 51 and the second electrode 40.

The second electrode 40 is located at the outside of the outer-periphery portion 6 of the silicon substrate 5 when viewed in a plan view. That is, the second electrode 40 is located outside the circumferential edge 5E of the silicon substrate 5 in the radially outward direction. In other words, the second electrode 40 is located in a space to which the circumferential edge 5E is exposed. The second electrode 40 is spaced apart from the circumferential edge 5E.

In this embodiment, the second electrode 40 has a circular-ring shape that surrounds the outer-periphery portion of the silicon substrate 5 when viewed in a plan view.

Note that, as long as it is possible to cause a Coulomb force to act on the resist liquid 51 such that at least part of the resist liquid 51 flows toward the circumferential edge 5E of the silicon substrate 5, the shape of the second electrode 40 is not limited to the circular-ring shape. For example, the second electrode 40 may have a cutout portion at which a part of the circular-ring shape is cut out in a circumferential direction of the silicon substrate 5. In other words, the second electrode 40 may have a substantially C-shape when viewed in a plan view.

Furthermore, the second electrode 40 may be formed by a plurality of divided electrodes which are arranged in the circumferential direction of the silicon substrate 5 at equal distance (at equal angles). In this case, for example, eight divided electrodes may be arranged at a 45-degree pitch in the circumferential direction of the silicon substrate 5. Note that, the number of the divided electrodes constituting the second electrode 40 is not limited to eight.

Additionally, as long as it is possible to cause a Coulomb force to act on the resist liquid 51 such that at least part of the resist liquid 51 flows toward the circumferential edge 5E of the silicon substrate 5, the divided electrodes may not be arranged at equal distance.

### <Electrode Mover>

The electrode mover 70 adjusts the position of the second electrode 40 in the Z-direction.

Therefore, the electrode mover 70 can control the position at which the second electrode 40 causes a Coulomb force to act on the resist liquid 51 in the Z-direction.

The electrode mover 70 can cause the second electrode 40 to be disposed closer to a top surface of the silicon substrate 5 than the center P of the silicon substrate 5 in the Z-direction. The top surface of the silicon substrate 5 is the surface to which the resist liquid 51 is to be supplied. In other words, the second electrode 40 can be disposed to be closer to the exposed portion (surface layer) of the resist liquid 51 in the Z-direction by the electrode mover 70. Furthermore, the position of the second electrode 40 in the Z-direction can also be set so as to correspond to the position of any one of the first layer 5A, the second layer 5B, and the third layer 5C which are formed on the silicon substrate 5.

### <Power Supply>

The power supply 60 is a high-voltage direct-current power supply and applies a direct-current voltage to the first electrode 30 and the second electrode 40. As the direct-current voltage of the power supply 60 which is applied to the first electrode 30 and the second electrode 40, for example, a range of approximately 10 V to 1 kV is adopted. The power supply 60 can independently apply a positive or a negative direct-current voltage to the first electrode 30 and the second electrode 40. The power supply 60 can set the voltage to be applied to the first electrode 30 and the voltage to be applied to the second electrode 40 to be the same as each other or to be different from each other.

### <Controller>

The controller 80 includes, for example, a control circuit. The controller 80 is electrically connected to each of the rotor 10, the ejector 20, the resist supply source 50, the power supply 60, and the electrode mover 70. The controller 80 controls operation of the resist coater 1. The controller 80 is, for example, a computer. The controller 80 includes a recording medium in which a computer program that carries out a plurality of steps of a semiconductor manufacturing method which will be described later is stored. The controller 80 executes each of the steps of the semiconductor manufacturing method using the resist coater 1. For example, the power supply 60 is controlled by the controller 80, and therefore it is possible to control the voltage value, the polarity, and the timing of applying voltage to each of the first electrode 30 and the second electrode 40. Moreover, the ejector 20 is controlled by the controller 80, and therefore it is possible to control movement of the nozzle 21, the angle of the nozzle 21, and the timing of ejecting the resist liquid 51 from the nozzle 21.

### <Resist Coating Method>

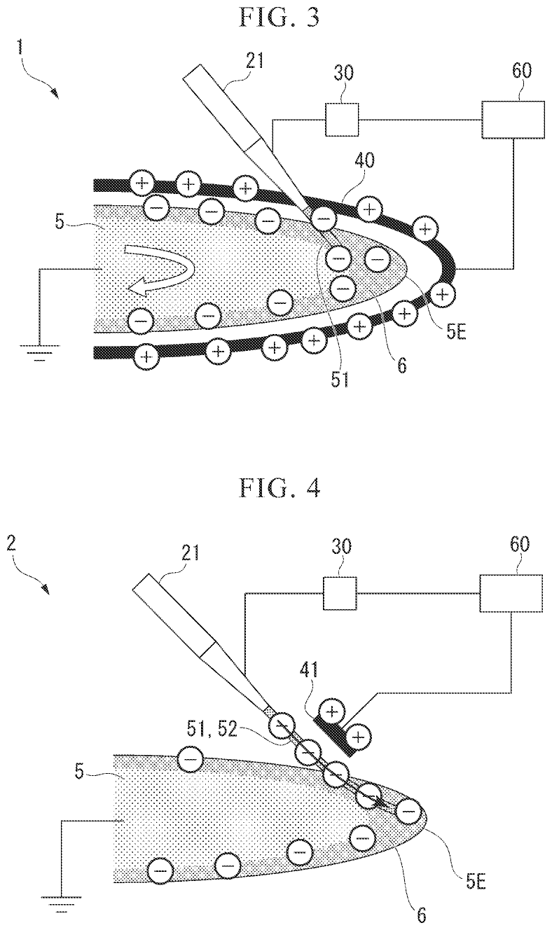

Next, a resist coating method using the resist coater 1 according to the first embodiment will be described. FIG. 3 is a view for explanation of the resist coating method using the resist coater 1 according to the first embodiment.

Firstly, the silicon substrate 5 is transferred to the resist coater 1 by a known transfer device, and the silicon substrate 5 is mounted on the spin chuck 11 of the rotor 10. The spin chuck 11 holds the silicon substrate 5. The motor 12 of the rotor 10 rotates the silicon substrate 5.

When the rotating speed of the silicon substrate 5 is stabilized, the nozzle-position adjuster 22 of the ejector 20 moves the nozzle 21 such that the nozzle 21 faces the outer-periphery portion 6 of the silicon substrate 5. For example, the nozzle-position adjuster 22 controls the ejection direction of the resist liquid 51 ejected from the nozzle 21 by causing the nozzle 21 to be inclined.

The power supply 60 applies a direct-current voltage to the first electrode 30. The nozzle 21 supplies the resist liquid 51 to the outer-periphery portion 6 of the silicon substrate 5. A positive electric charge is applied to the resist liquid 51 ejected from the nozzle 21 due to the application of the direct-current voltage from the first electrode 30 to the nozzle 21.

Since the electrical potential of the silicon substrate 5 is the ground potential, the polarity of the resist liquid 51 is switched from positive to negative when the resist liquid 51 is applied on the silicon substrate 5.

The resist liquid 51 applied on the outer-periphery portion 6 of the silicon substrate 5 flows toward the circumferential edge 5E of the silicon substrate 5 via the action of centrifugal force due to the rotation of the silicon substrate 5.

The power supply 60 applies a direct-current voltage to the second electrode 40, and therefore the polarity of the second electrode 40 is switched to positive. Consequently, a Coulomb force is generated on the resist liquid 51 between the resist liquid 51 having the negative electric charge and the second electrode 40 having the positive polarity. That is, the Coulomb force acts on the resist liquid 51 such that at least part of the resist liquid 51 flows toward the circumferential edge 5E of the silicon substrate 5.

When the above-described Coulomb force acts on the resist liquid 51, the resist liquid 51 is dried while the resist liquid 51 is caused to come into contact with ambient air around the silicon substrate 5 by the rotation of the silicon substrate 5. When the resist liquid 51 is dried, a resist film is formed on the outer-periphery portion 6.

According to the above-described resist coater 1, as well as a centrifugal force acting on the resist liquid 51 that is applied on the outer-periphery portion 6 of the silicon substrate 5 due to the rotation of the rotor 10, it is also possible to cause a Coulomb force to act on the resist liquid 51 via the second electrode 40 that is located outside the circumferential edge 5E of the silicon substrate 5. When the Coulomb force acts on the resist liquid 51, it is possible to dry the resist liquid 51 on the outer-periphery portion 6 of the silicon substrate 5.

For this reason, it is possible to control the shape and the profile of the resist film formed on the outer-periphery portion 6 of the silicon substrate 5. Additionally, it is possible to control the position or the height (thickness) of a portion (hump) having a locally large film thickness of the resist film obtained by drying the resist liquid 51.

Note that, in this embodiment, before the resist liquid 51 is applied on the outer-periphery portion 6 of the silicon substrate 5, the position of the second electrode 40 in the Z-direction is set by the electrode mover 70. For example, in this embodiment, the second electrode 40 is disposed closer to the top surface of the silicon substrate 5 (the surface of the third layer 5C) than the center P of the silicon substrate 5 in the Z-direction. Consequently, the Coulomb force can be generated at a region close to the top surface of the silicon substrate 5, and it is possible to cause the resist liquid 51 to be flat with a high degree of accuracy on the top surface of the silicon substrate 5.

In this embodiment, the position of the second electrode 40 is set by the electrode mover 70 before application of the resist liquid 51; however, this embodiment is not limited to this setting method. The electrode mover 70 may adjust the position of the second electrode 40 while applying the resist liquid 51 from the nozzle 21 on the silicon substrate 5. In other words, the position of the second electrode 40 may be controlled while causing the resist liquid 51 applied on the silicon substrate 5 to flow to the outer-periphery portion 6.

Because of this, it is possible to apply a Coulomb force to the flowing resist liquid 51, and it is possible to control the shape and the profile of the resist film.

Furthermore, the resist coating method according to this embodiment includes a resist application step. The resist application step is started by supplying the resist liquid 51 from the nozzle 21 to the outer-periphery portion 6 in a state in which the silicon substrate 5 is rotated by the motor 12. The resist application step is finished by stopping the supply of the resist liquid 51. In such a resist application step, the supply of the resist liquid 51 is completed while causing a Coulomb force to act on the resist liquid 51 by the second electrode 40 such that at least pan of the resist liquid 51 flows toward the circumferential edge 5E of the silicon substrate 5.

Consequently, it is possible to cause the Coulomb force to act on the resist liquid 51 until the supply of the resist liquid 51 is completed, and it is possible to cause the resist liquid 51 to be flat with a high degree of accuracy on the top surface of the silicon substrate 5.

### Second Embodiment

FIG. 4 is a view for explanation of the resist coating method using a resist coater 2 according to a second embodiment. FIG. 4 is a perspective view corresponding to FIG. 3 and showing the resist coater 2 according to the second embodiment. This embodiment is different from the first embodiment in a configuration of the second electrode.

### <Second Electrode>

A second electrode 41 shown in FIG. 4 is disposed so as to face an ejection pathway 52 (ejected liquid, ejected liquid pillar) of the resist liquid 51. The ejection pathway 52 is a pathway through which the resist liquid 51 ejected from the nozzle 21 reaches the outer-periphery portion 6 of the silicon substrate 5. For example, the second electrode 41 is disposed at a position at which the second electrode 41 faces the silicon substrate 5 in the Z-direction (that is, above the silicon substrate 5). In this embodiment, the second electrode 41 is disposed outside and above the ejection pathway 52.

Before the ejected resist liquid 51 ejected from the nozzle 21 reaches the outer-periphery portion 6, the second electrode 41 causes a Coulomb force to act on the resist liquid 51 such that the Coulomb force acts on the incidence angle of the ejection pathway 52 with respect to the circumferential edge 5E of the silicon substrate 5. By controlling the direct-current voltage supplied from the power supply 60 to the second electrode 41, the amount of the Coulomb force generated from the second electrode 41 is controlled, and an increase or a decrease in the incidence angle of the ejection pathway 52 is controlled.

Particularly, the Coulomb force generated between the second electrode 41 and the resist liquid 51 acts on the incidence angle of the ejection pathway 52, and the Coulomb force causes the resist liquid 51 to flow such that at least part of the resist liquid 51 flows toward the circumferential edge 5E of the silicon substrate 5. In other words, the Coulomb force generated from the second electrode 41 causes the resist liquid 51 to flow so as to guide at least part of the resist liquid 51 toward the circumferential edge 5E of the silicon substrate 5.

### <Resist Coating Method>

Next, a resist coating method using the resist coater 2 will be described.

Similarly to the aforementioned first embodiment, the nozzle 21 supplies the resist liquid 51 to the outer-periphery portion 6 of the silicon substrate 5. However, the resist coating method using the resist coater 2 is different from that of the above-mentioned first embodiment, a negative direct-current voltage is applied to the nozzle 21 from the first electrode 30 by the power supply 60, and a first polarity electric charge (for example, a negative electric charge) is applied to the resist liquid 51 ejected from the nozzle 21.

On the other hand, the power supply 60 applies a direct-current voltage to the second electrode 41, and therefore an electric charge having a second polarity (for example, a positive electric charge) is applied to the second electrode 41.

Consequently, a Coulomb force is generated on the resist liquid 51 between the resist liquid 51 having the first polarity electric charge (for example, a negative electric charge) and the second electrode 41 having the second polarity (for example, a positive polarity) on the ejection pathway 52. That is, the Coulomb force acts on the resist liquid 51 such that at least part of the resist liquid 51 flows toward the circumferential edge 5E of the silicon substrate 5.

According to the above-described resist coater 2, as well as being possible to obtain the same or similar effects as those of the above-described first embodiment, it is also possible to control the incidence angle of the ejection pathway 52 (the resist liquid 51) with respect to the circumferential edge 5E of the silicon substrate 5 via the action of the Coulomb force generated between the second electrode 41 and the resist liquid 51. As a result, when the resist liquid 51 is applied on the silicon substrate 5, it is possible to inhibit the resist liquid 51 from being bounced back from the silicon substrate 5, and it is possible to control the profile of the resist liquid 51 on the silicon substrate 5 with a high degree of accuracy.

### Third Embodiment

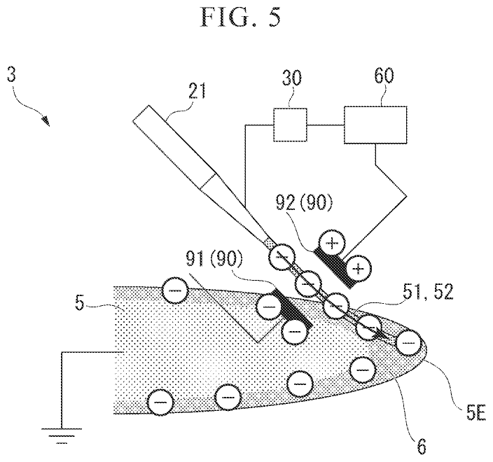

FIG. 5 is a view for explanation of the resist coating method using a resist coater 3 according to a third embodiment. FIG. 5 is a perspective view corresponding to FIG. 3 and showing the resist coater 3 according to the third embodiment. This embodiment is different from the first embodiment in that an electrostatic deflector includes a second electrode.

The resist coater 3 includes an electrostatic deflector 90. The electrostatic deflector 90 is disposed so as to face the ejection pathway 52 of the resist liquid 51. The ejection pathway 52 is a pathway through which the resist liquid 51 ejected from the nozzle 21 reaches the outer-periphery portion 6 of the silicon substrate 5.

### <Electrostatic Deflector>

As shown in FIG. 5, the electrostatic deflector 90 includes a first deflection electrode 91 and a second deflection electrode 92. The first deflection electrode 91 and the second deflection electrode 92 are connected to the power supply 60. The power supply 60 sets the polarity of each of the first deflection electrode 91 and the second deflection electrode 92. At least one of the first deflection electrode 91 and the second deflection electrode 92 is an example of a “second electrode”.

In this embodiment, the first deflection electrode 91 has a negative polarity (first polarity), and the second deflection electrode 92 has a positive polarity (a second polarity opposite to the first polarity). Each of the first deflection electrode 91 and the second deflection electrode 92 is connected to the power supply 60.

For example, the power supply 60 is controlled by the controller 80, and therefore it is possible to control the voltage value, the polarity, and the timing of applying voltage to each of the first deflection electrode 91 and the second deflection electrode 92.

The first deflection electrode 91 and the second deflection electrode 92 are disposed so as to sandwich the ejection pathway 52 therebetween. For example, the first deflection electrode 91 and the second deflection electrode 92 are disposed at the position at which the first deflection electrode 91 and the second deflection electrode 92 face the silicon substrate 5 in the Z-direction (that is, above the silicon substrate 5).

In this embodiment, the first deflection electrode 91 is disposed under the ejection pathway 52 and is disposed closer to the center region 7 of the silicon substrate 5 than the second deflection electrode 92. On the other hand, the second deflection electrode 92 is disposed outside and above the ejection pathway 52. The second deflection electrode 92 is disposed closer to the circumferential edge 5E of the silicon substrate 5 than the first deflection electrode 91.

Before the ejected resist liquid 51 ejected from the nozzle 21 reaches the outer-periphery portion 6, the electrostatic deflector 90 causes a Coulomb force to act on the resist liquid 51 such that the Coulomb force acts on the incidence angle of the ejection pathway 52 with respect to the circumferential edge 5E of the silicon substrate 5. By controlling the direct-current voltage and the polarities supplied from the power supply 60 to the first deflection electrode 91 and the second deflection electrode 92, the amount of the Coulomb force generated from the electrostatic deflector 90 is controlled, and an increase or a decrease in the incidence angle of the ejection pathway 52 is controlled.

Particularly, the Coulomb force generated between the electrostatic deflector 90 and the resist liquid 51 acts on the incidence angle of the ejection pathway 52, and the Coulomb force causes the resist liquid 51 to flow such that at least part of the resist liquid 51 flows toward the circumferential edge 5E of the silicon substrate 5. In other words, the Coulomb force generated from the electrostatic deflector 90 causes the resist liquid 51 to flow so as to guide at least part of the resist liquid 51 toward the circumferential edge 5E of the silicon substrate 5.

### <Resist Coating Method>

Next, a resist coating method using the resist coater 3 will be described.

Similarly to the aforementioned first embodiment, the nozzle 21 supplies the resist liquid 51 to the outer-periphery portion 6 of the silicon substrate 5. Similarly to the aforementioned second embodiment, a negative direct-current voltage is applied to the nozzle 21 from the first electrode 30 by the power supply 60, and a negative electric charge is applied to the resist liquid 51 ejected from the nozzle 21.

In the electrostatic deflector 90, the power supply 60 applies a negative electric charge to the first deflection electrode 91, and the power supply 60 applies a positive electric charge to the second deflection electrode 92.

Accordingly, between the resist liquid 51 having the negative electric charge on the ejection pathway 52 and the second deflection electrode 92 having the positive polarity, the Coulomb force acts on the resist liquid 51 such that at least part of the resist liquid 51 flows toward the circumferential edge 5E of the silicon substrate 5.

According to the above-described resist coater 3, as well as being possible to obtain the same or similar effects as those of the above-described first embodiment, it is also possible to control the incidence angle of the ejection pathway 52 (the resist liquid 51) with respect to the circumferential edge 5E of the silicon substrate 5 via the action of the Coulomb force generated between the electrostatic deflector 90 and the resist liquid 51. As a result, when the resist liquid 51 is applied on the silicon substrate 5, it is possible to inhibit the resist liquid 51 from being bounced back from the silicon substrate 5, and it is possible to control the profile of the resist liquid 51 on the silicon substrate 5 with a high degree of accuracy.

Note that, the electrostatic deflector 90 needs to at least cause a Coulomb force to act on the resist liquid 51 so as to change the ejection direction of the resist liquid 51, and the action of the Coulomb force may be achieved by only one of the first deflection electrode 91 and the second deflection electrode 92.

According to at least one embodiment described above, by providing a first electrode that applies an electric charge to resist liquid ejected from a nozzle and a second electrode that is disposed at a position different from that of the first electrode and that causes a Coulomb force to act on the resist liquid such that at least part of the resist liquid is directed to the circumferential edge of the substrate, it is possible to stabilize a process.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus comprising:
a rotor configured to hold a substrate, the rotor being configured to rotate the substrate, the substrate having an outer-periphery portion and a circumferential edge, the circumferential edge being outside the outer-periphery portion;
a nozzle configured to supply a resist liquid to the outer-periphery portion of the substrate;
a first electrode configured to receive a voltage that applies an electric charge to the resist liquid ejected from the nozzle; and
a second electrode disposed at a position different from that of the first electrode, the second electrode being configured to receive a voltage that causes a Coulomb force to act on the resist liquid.

2. The semiconductor manufacturing apparatus according to claim 1, wherein
the second electrode is located outside the circumferential edge of the substrate.

3. The semiconductor manufacturing apparatus according to claim 2, wherein
the second electrode has a circular-ring shape that surrounds the outer-periphery portion of the substrate.

4. The semiconductor manufacturing apparatus according to claim 1, further comprising:
an electrode mover adjusting a position of the second electrode in a thickness direction of the substrate.

5. The semiconductor manufacturing apparatus according to claim 1, wherein
the second electrode is disposed closer to a top surface of the substrate than a center of the substrate in a thickness direction of the substrate, and
the resist liquid is to be supplied to the top surface of the substrate.

6. The semiconductor manufacturing apparatus according to claim 1, wherein
the second electrode is disposed so as to face an ejection pathway through which the resist liquid ejected from the nozzle reaches the outer-periphery portion of the substrate, and
the second electrode causes the Coulomb force to act on the resist liquid such that the Coulomb force acts on an incidence angle of the ejection pathway with respect to the outer-periphery portion of the substrate before the resist liquid ejected from the nozzle reaches the outer-periphery portion.

7. The semiconductor manufacturing apparatus according to claim 1, further comprising:
an electrostatic deflector disposed so as to face an ejection pathway through which the resist liquid ejected from the nozzle reaches the outer-periphery portion of the substrate, wherein
the electrostatic deflector includes:
a first deflection electrode having a first polarity; and
a second deflection electrode having a second polarity opposite to the first polarity, the second deflection electrode forming the second electrode, and wherein
the first deflection electrode and the second deflection electrode are disposed so as to sandwich the ejection pathway therebetween, and
the electrostatic deflector causes the Coulomb force to act on the resist liquid such that the Coulomb force acts on an incidence angle of the ejection pathway with respect to the outer-periphery portion of the substrate before the resist liquid ejected from the nozzle reaches the outer-periphery portion.

8. A semiconductor manufacturing method comprising:
rotating a substrate by a rotor while holding the substrate, the substrate having an outer-periphery portion and a circumferential edge, the circumferential edge being outside the outer-periphery portion;
supplying a resist liquid to the outer-periphery portion of the substrate from a nozzle;
using a first electrode, applying an electric charge to the resist liquid ejected from the nozzle; and
using a second electrode disposed at a position different from that of the first electrode, the second electrode being configured to receive a voltage that causes a Coulomb force to act on the resist liquid.

9. The semiconductor manufacturing method according to claim 8, further comprising:
drying the resist liquid while causing a Coulomb force to act on the resist liquid and causing at least part of the resist liquid to be directed to the circumferential edge of the substrate by the second electrode.

10. The semiconductor manufacturing method according to claim 8, further comprising:
completing supply of the resist liquid while causing a Coulomb force to act on the resist liquid and causing at least part of the resist liquid to be directed to the circumferential edge of the substrate by the second electrode.
